(19) United States
(12) Patent Application Publication
(10) Pub. No.: US 2013/0070168 A1
(43) Pub. Date: Mar. 21, 2013

(54) LED LIGHT SOURCE, LED BACKLIGHT, LIQUID CRYSTAL DISPLAY DEVICE AND TV RECEPTION DEVICE

(71) Applicant: Masashi Yokota, Osaka (JP)

(72) Inventor: Masashi Yokota, Osaka (JP)

(73) Assignee: SHARP KABUSHIKI KAISHA, Osaka (JP)

(21) Appl. No.: 13/699,469

(22) PCT Filed: Feb. 4, 2011
(86) PCT No.: PCT/JP2011/052350

§ 371 Date: Nov. 21, 2012

(30) Foreign Application Priority Data
May 26, 2010 (JP) 2010-120427

(51) Int. Cl. H04N 7/00; H01L 33/44; G02F 1/1335; H01L 33/08

(52) U.S. Cl. CPC H04N 7/00; H01L 33/08; H01L 33/44; G02F 1/133603
USPC 348/790; 257/89; 349/64; 348/E07.001

(57) ABSTRACT

In order to provide an LED light source and an LED backlight in which color variations in the chromaticity of light emitted from a light emitting surface are not produced and in which the brightness on a display screen is made uniform, an LED light source provided with an LED chip that emits light of a predetermined color and a sealing resin that contains a fluorescent material are included. The fluorescent material includes a plurality of fluorescent materials that emit excitation light of a plurality of different wavelengths within the excitation light wavelength range of the predetermined color, and the light emitting surface is formed in the shape of a diffusion lens portion that adjusts the light emitted and distributed. Also, the application regions of the adjacent LED light sources overlap each other, and thus it is possible to obtain an LED backlight.

### TECHNICAL FIELD

The present invention relates to a backlight that applies light to a liquid crystal panel from behind and a liquid crystal display device and a TV reception device that incorporate such a backlight. More particularly, the present invention relates to an LED light source, an LED backlight, a liquid crystal display device and a TV reception device that use an LED as a light source.

### BACKGROUND ART

In recent years, as light emission efficiency has been enhanced and the amount of light emitted has been increased, an illumination device using an LED (light emitting diode) in which its life is increased and its power consumption is low and which is environmentally-friendly has been commercially available. Since the development of a blue LED chip, a white LED light source that combines the blue LED chip with a fluorescent material which is excited by light from the LED chip to emit excitation light having a predetermined wavelength and that emits white light and a white LED light source that uses and combines LED chips of three primary colors, namely, the blue LED chip, a green LED chip and a red LED chip to generate white light have been developed.

Hence, as the backlights of a liquid crystal display device, a TV reception device and the like having a liquid crystal panel, an LED backlight is used in which the white LED light source described above is provided. As these backlights, there are known a direct-type backlight in which a light source is arranged on the back surface of a display screen and an edge light-type backlight in which a light source is arranged on the side portion of a display screen, a light guide plate is arranged on the back surface of the display screen, light is made to enter the light guide plate through the side portion of the display screen, the light is reflected within the light guide plate and planar light is emitted from the light emitting surface of the light guide plate.

Since, in the edge light-type backlight, a light source portion is provided on the side portion of the display screen, and the plate-shaped light guide plate is arranged on the back surface of the display screen, the thickness of the edge light-type backlight is easily reduced, and thus it is preferably used to reduce the thickness of a liquid crystal display device or the like. Since, in the direct-type backlight, the light source is arranged on the back surface of the display screen to directly apply light, high-brightness illumination and control on light emission brightness in each area are easily performed, with the result that the direct-type backlight is preferably used.

In the backlight using the LED, in order to uniformly diffuse light emitted from the LED and increase its brightness, optical members such as a diffusion plate and a lens sheet are provided between the LED backlight and the liquid crystal panel.

However, in the direct-type backlight using the LED, even if the optical members such as the diffusion plate and the lens sheet are provided between the LED backlight and the liquid crystal panel because each LED produces variations in brightness in an area, variations in the light emission chromaticity of each LED light source, variations in application angle and the like may cause variations in brightness.

Hence, as an illumination device that combines a blue LED and a fluorescent sheet to obtain white light, an illumination device has already been disclosed in which diffusion plates are provided on both the surface of the fluorescent sheet on the light entrance side and the surface on the light emitting side so as to cope with variations in the chromaticity of incoming light and to reduce variations in the chromaticity caused by the viewing angle of emitted light (see, for example, patent document 1).

### RELATED ART DOCUMENT

### Patent Document

Patent document 1: JP-A-2009-283438

### DISCLOSURE OF THE INVENTION

### Problems to be Solved by the Invention

When an LED light source is a white LED light source obtained by sealing a blue LED chip with a transparent resin containing a fluorescent material, light having a light emission peak of a predetermined wavelength produced by the blue LED chip and a light emission peak of a predetermined wavelength of light emitted by the fluorescent material is emitted. Thus, the light emitted from the white light source as described above has a relatively narrow light emitting characteristic.

In the fluorescent material contained in the LED light source, since variations in particle diameter are produced in a manufacturing process, the fluorescent material whose particle diameter falls within a predetermined range of sizes is sorted and used. However, even if the particle diameter falls within the predetermined range, when the fluorescent material is contained, variations in the position where the fluorescent material is contained are produced according to the particle diameter, with the result that variations in light emission chromaticity are disadvantageously produced according to the emission direction.

Hence, in the LED direct-type backlight in which a plurality of LED light sources are provided in the back surface portion of a liquid crystal panel, the narrowness of the light emission characteristic and variations in the light emission chromaticity of each LED light source as described above disadvantageously cause variations in color on the light emitting surface.

As with the illumination device disclosed in patent document 1, in a device that uses a blue LED light source and a fluorescent sheet having diffusion plates on both the light entrance surface and the light emitting surface, though it is possible to reduce variations in chromaticity, it is necessary to manufacture not only the two diffusion plates but also a fluorescent sheet containing a predetermined fluorescent material, with the result that its cost is increased. Hence, it is undesired to use such a device.

Hence, preferably, when a direct-type LED is used to form a backlight for a liquid crystal panel, an LED backlight is formed such that variations in the light emission characteristic of each LED light source are reduced with a simpler configuration to prevent color variations in the chromaticity of the light emitted from the light emitting surface, variations in color caused by errors in the manufacturing of the individual LED light sources are reduced and the brightness on the display screen is made uniform.

Hence, in view of the foregoing problem, the present invention has an object to provide an LED light source that can reduce variations in the light emission characteristic of each LED light source with a simpler configuration, in a direct-type LED backlight and a liquid crystal display device and a TV reception device incorporating such a backlight and to provide an LED backlight in which no color variations in the chromaticity of light emitted from a light emitting surface are produced and in which the brightness on the display screen is made uniform.

### Means for Solving the Problem

To achieve the above object, according to the present invention, there is provided an LED light source including: an LED chip that emits first light of a predetermined color; a mounting substrate on which the LED chip is mounted; and a sealing resin that contains a fluorescent material which receives the light from the LED chip to emit second light in an excitation light wavelength range of a predetermined color, the LED light source emitting, from a light emitting surface, third light obtained by mixing the first light and the second light, in which the fluorescent material includes a plurality of types of fluorescent materials that emit excitation light of a plurality of different wavelengths within the excitation light wavelength range of the predetermined color, and the light emitting surface is formed in a shape of a diffusion lens portion that adjusts light emitted and distributed.

In this configuration, since the excitation light of the predetermined color emitted by the fluorescent material has a plurality of light emission peaks, even if a relatively wide light emission characteristic is produced, and variations in the mixing of the fluorescent materials in each LED light source are produced, variations in the light emission characteristic of the LED light source are reduced. In other words, it is possible to obtain an LED light source that has a simple configuration and that can reduce variations in the light emission characteristic of each LED light source. Since the emitting surface is formed in the shape of a diffusion lens, it is possible to adjust the intensity of light emitted from the emitting surface, diffuse it in a predetermined range and emit it, and thus it is possible to mix and easily average the light emission of the adjacent LED light sources, with the result that it is possible to obtain an LED light source capable of reducing the occurrence of color variations.

In the LED light source of the present invention configured as described above, the sealing resin is solidified to have such a shape as to have a light emission peak at a high diffusion angle such that the sealing resin forms the diffusion lens portion. In this configuration, since the hue is averaged using the sealing resin solidified to have such a shape as to have a light emission brightness peak at a high diffusion angle, it is possible to obtain an LED light source that has a simpler configuration and that can reduce the occurrence of color variations.

In the LED light source of the present invention configured as described above, the first light is blue light, the LED chip is a blue LED chip that emits blue light, the second light is red light and green light, the fluorescent material is a red fluorescent material that receives the blue light to emit red excitation light and a green fluorescent material that receives the blue light to emit green excitation light and the green fluorescent material includes a plurality of green fluorescent materials that emit green light of different wavelengths. In this configuration, a light emission characteristic over the wide range of a green light emission wavelength region is produced, and it is possible to obtain an LED light source that can reduce variations in the light emission characteristic of the LED light source.

In the LED light source of the present invention configured as described above, the green fluorescent material is formed with a first green fluorescent material and a second green fluorescent material having different excitation wavelengths. In this configuration, the two types of green fluorescent materials are mixed, and thus it is possible to obtain an LED light source that can reduce variations in the light emission characteristic of the LED light source.

In the LED light source of the present invention configured as described above, the first light is blue light, the LED chip is a blue LED chip that emits blue light, the second light is red light and green light, the fluorescent material is a red fluorescent material that receives the blue light to emit red excitation light and a green fluorescent material that receives the blue light to emit green excitation light and the red fluorescent material includes a plurality of red fluorescent materials that emit red light of different wavelengths. In this configuration, a plurality of light emission peaks are produced in the red light emission wavelength region, and thus it is possible to obtain an LED light source that can reduce variations in the light emission characteristic of the LED light source.

In the LED light source of the present invention configured as described above, the red fluorescent material is formed with a first red fluorescent material and a second red fluorescent material having different excitation wavelengths. In this configuration, the two types of red fluorescent materials are mixed, and thus it is possible to obtain an LED light source that can reduce variations in the light emission characteristic of the LED light source.

In the LED light source of the present invention configured as described above, the first light is blue light, the LED chip is a blue LED chip that emits blue light, the second light is red light and green light, the fluorescent material is a red fluorescent material that receives the blue light to emit red excitation light and a green fluorescent material that receives the blue light to emit green excitation light, the red fluorescent material includes a plurality of red fluorescent materials that emit red light of different wavelengths and the green fluorescent material includes a plurality of green fluorescent materials that emit green light of different wavelengths. In this configuration, a plurality of light emission peaks are produced in each of the red and green light emission wavelength regions, and thus it is possible to obtain an LED light source that can more reduce variations in the light emission characteristic of the LED light source.

In the LED light source of the present invention configured as described above, the solidified sealing resin is shaped to include a center concave portion where an upper portion of the LED chip is depressed in a concave form and a ring-shaped convex portion where a circumference thereof protrudes in a ring-shaped convex form and is formed in a shape of a curved surface having a predetermined curvature that increases a light intensity in a predetermined diffusion direction. In this configuration, the intensity of light emitted from the LED light source in the normal direction is lowered, the light intensity in a diffusion position open at a predetermined angle is increased, the application ranges of the adjacent LED light sources are provided to overlap each other when a plurality of LED light sources are aligned and thus it is possible to mix and easily average the light of a plurality of LED light sources.

In the LED light source of the present invention configured as described above, the curvatures of the center concave portion and the ring-shaped convex portion have a light emission peak at a high diffusion angle, and furthermore, the center concave portion and the ring-shaped convex portion are solidified to have such a shape as to also produce a predetermined light emission intensity in a normal direction. In this configuration, the light intensity in the normal direction is made equal to a predetermined light emission intensity, and thus it is possible to obtain an LED light source that can enhance the front surface brightness on the display screen and that is suitable for the LED backlight.

According to the present invention, in a direct-type LED backlight in which a plurality of LED light sources arranged on a back surface of a liquid crystal panel applies light to the liquid crystal panel, as the LED light source, the LED light source of any one of claims 1 to 9 is included. In this configuration, since it is possible to reduce variations in the light emission characteristic of each LED light source and diffuse and emit the light emitted from the LED light source, the light emitted from the adjacent LED light sources is easily mixed, and thus it is possible to reduce color variations in chromaticity. Hence, it is possible to obtain, even if the emission characteristic of the LED light source depends on the color, a direct-type LED backlight that can reduce variations as the backlight and stabilize the color reproduction range of the light emission colors.

In the LED backlight of the present invention configured as described above, the plurality of LED light sources are provided such that application regions of adjacent LED light sources overlap each other. In this configuration, it is possible to mix and average the light from the adjacent LED light sources and obtain an LED backlight in which the brightness on the display screen is easily made uniform and color variations in the chromaticity of the emitted light are more unlikely to be produced.

According to the present invention, there is provided a liquid crystal display device including: a liquid crystal panel; and the LED backlight of claim 10 or 11. In this configuration, an LED backlight is used which reduces variations in the light emission characteristic of each LED light source, in which color variations in the chromaticity of the light emitted from the light emitting surface are not produced and which makes uniform the brightness on the display screen, and thus it is possible to obtain a liquid crystal display device that reduces variations in color on the entire display screen and that enhances the display quality.

According to the present invention, there is provided a TV reception device including: the liquid crystal display device of claim 12. In this configuration, an LED backlight is used which reduces variations in the light emission characteristic of each LED light source, in which color variations in the chromaticity of the light emitted from the light emitting surface are not produced and which makes uniform the brightness on the display screen, and thus it is possible to obtain a TV reception device that reduces variations in color on the entire display screen and that enhances the display quality.

### Advantages of the Invention

According to the present invention, in a direct-type LED backlight and a liquid crystal display device incorporating such a backlight, it is possible to obtain an LED light source that can reduce variations in the light emission characteristic, and it is possible to obtain an LED backlight in which the brightness on the display screen is easily made uniform and color variations in the chromaticity of the emitted light are unlikely to be produced. With this LED backlight, it is possible to obtain a liquid crystal display device and a TV reception device that reduce variations in color on the entire display screen and enhance the display quality.

### BRIEF DESCRIPTION OF DRAWINGS

FIG. 1 An enlarged diagram illustrating an LED light source incorporated in an LED backlight according to the present invention;

FIG. 2 An enlarged diagram illustrating a variation of the LED light source shown in FIG. 1;

FIG. 3 A diagram of light intensity illustrating the light emission characteristic of the LED light source in which the horizontal axis represents an optical diffusion angle and the vertical axis represents a light intensity;

FIG. 4 A graph illustrating the light emission spectrum of the LED light source in which the horizontal axis represents a wavelength and the vertical axis represents a light intensity;

FIG. 5 A schematic plan view illustrating a light emission region by the LED backlight according to the present invention; and

FIG. 6 A schematic cross-sectional view showing the configuration of a liquid crystal display device incorporating the LED backlight according to the present invention.

### DESCRIPTION OF EMBODIMENTS

An embodiment of the present invention will be described below with reference to accompanying drawings. Like constituent members are identified with like symbols, and their detailed description will be omitted as necessary.

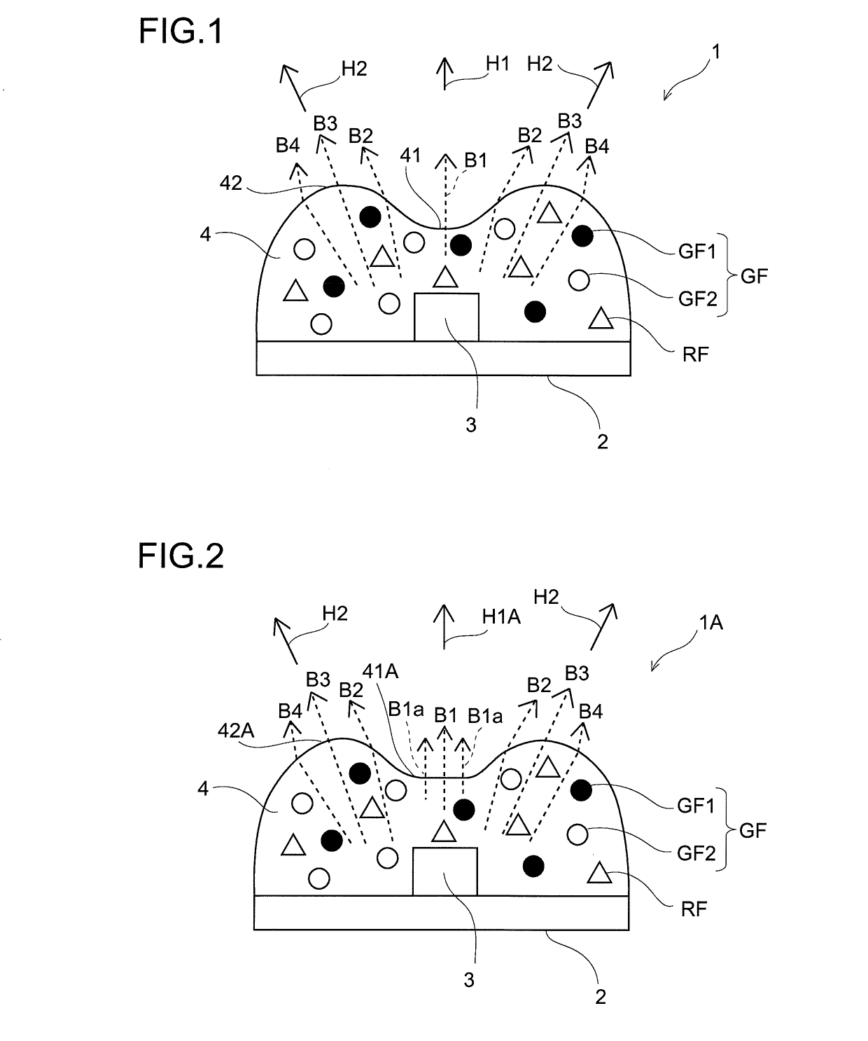

An LED light source of the present invention is a light source that is used in a direct-type backlight of a liquid crystal display device; a plurality of LED light sources are provided on the back surface of a liquid crystal panel. The LED light source 1 of the present embodiment will be described with reference to FIG. 1.

In the LED light source 1 shown in FIG. 1, an LED chip 3 is mounted on a mounting substrate 2 (sub-mount substrate), a plurality of fluorescent materials (GF1, GF2 and RF) are contained in a transparent sealing resin 4, such as a silicone resin or an epoxy resin, that has translucency, in predetermined proportions, and third light obtained by combining first light emitted by the LED chip 3 with second light emitted by the excitation of the fluorescent materials by the first light is emitted.

The first light is, for example, blue light; the LED chip 3 is a blue LED chip that emits light having a predetermined blue light wavelength. The fluorescent material is, for example, a red fluorescent material RF that emits red excitation light by receiving the blue light emitted by the LED chip 3 and a green fluorescent material GF that emits green excitation light by receiving the blue light. The blue light that is emitted by the LED chip 3 and that is the first light and the red light and the blue light that are emitted by the fluorescent materials and that are the second light are mixed, and thus white light is emitted as the combined third light.

Here, in the present embodiment, the fluorescent material that emits light in an excitation light wavelength range of a predetermined color further includes a plurality of types of fluorescent materials that emit excitation light having a plurality of different wavelengths within the excitation light wavelength range of the predetermined color.

The emitting surface is formed in the shape of a diffusion lens that adjusts light emitted and distributed. Thus, it is possible to adjust the intensity of light emitted from the emitting surface, diffuse it in a predetermined range and emit it, and light emitted from adjacent LED light sources is easily mixed and averaged, with the result that it is possible to obtain the LED light source which can reduce the occurrence of variations in color.

As a method of forming the emitting surface in the shape of the diffusion lens, there are a method of attaching the diffusion lens to the emitting surface, a method of solidifying the sealing resin 4 in the shape of the diffusion lens and the like; in order to obtain, with a simpler configuration and a low cost, the LED light source that can reduce the occurrence of variations in color, it is preferable to solidify and use the sealing resin in a shape having a light emission brightness peak at a high diffusion angle.

Hence, in the present embodiment, the sealing resin 4 is solidified to have such a shape as to include a center concave portion 41 where the top portion of the LED chip 3 is depressed in a concave form and a ring-shaped convex portion 42 where its circumference protrudes in a ring-shaped convex form. As described above, the emitting surface of the sealing resin 4 is formed in such a shape as to include the center concave portion 41 and the ring-shaped convex portion 42, and thus the emitted light is converged in a predetermined direction corresponding to the curvature of a curve due to the lens effect of the ring-shaped convex portion 42, with the result that the light intensity in a direction diffused at a predetermined angle is increased. In other words, the LED light source 1 has a light emission peak at a high diffusion angle.

For example, light B1 shown in the figure represents light that passes through the center concave portion 41 and that is emitted directly from the LED chip 3, and light B2, light B3 and light B4 represent diffusion light that passes through the ring-shaped convex portion 42 and that is converged in a direction diffused at a predetermined angle due to the lens effect of the ring-shaped convex portion 42.

Hence, the ring-shaped convex portion 42 is formed in the shape of a curve having such a predetermined curvature as to increase the light intensity in a predetermined diffusion direction, and thus it is possible to reduce the intensity of light emitted from the LED light source 1 in a normal direction without the light intensity becoming excessively high, with the result that it is possible to increase the light intensity in a diffusion position open at a predetermined angle. Since light is emitted from each LED light source and is brought into a high diffusion state, light emitted from adjacent LED light sources can be mixed and easily averaged.

In the LED light source 1 configured as describe above, as shown in FIG. 1, the intensity of light H1 emitted from the LED light source 1 in the normal direction is lowered, and the intensity of light H2 in a diffusion position at an open angle is increased, with the result that it is possible to emit light diffused at a predetermined angle. In other words, the LED light source 1 configured as described above is a diffusion-type LED light source.

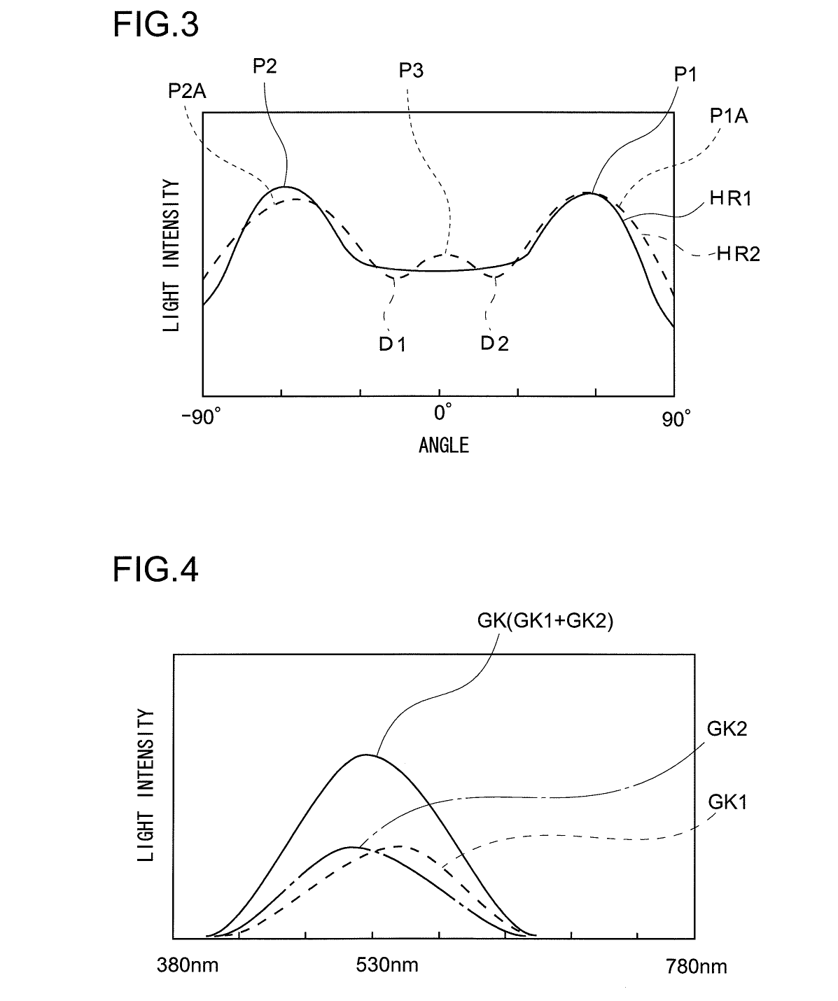

For example, the diffusion-type LED light source 1 having the shape shown in FIG. 1 emits, as in a light emission characteristic HR1 represented by the solid line of FIG. 3, light whose intensity is low in the normal direction and which has light emission peaks P1 and P2 in diffusion positions open at predetermined angles.

A light emission characteristic HR2 represented by the broken line of the figure shows an example where an LED light source 1A described later is used to slightly increase the light intensity in a direct emission direction of the LED light source, that is, in the normal direction and thus a third light emission peak P3 is produced. The curvatures of the center concave portion 41 and the ring-shaped convex portion 42 described above have the light emission peak at a high diffusion angle, and furthermore they are solidified to have such a shape as to also produce a predetermined light emission intensity in the normal direction, with the result that it is possible to realize the light emission characteristic HR2.

A variation where the light intensity in the normal direction is slightly increased will be described with reference to FIG. 2.

The LED light source 1A shown in FIG. 2 differs from the LED light source 1 described above in that the LED light source 1A has a light emission peak at a high diffusion angle and further includes a center concave portion 41A and a ring-shaped convex portion 42A which are solidified to have such a shape as to also produce a predetermined light emission intensity in the normal direction. The other configurations are the same, and thus their detailed description will not be repeated.

Even in this configuration, the light B2, the light B3 and the light B4 that pass through the ring-shaped convex portion 42A are converged in a direction diffused at a predetermined angle due to the lens effect of the ring-shaped convex portion 42A, and thus diffusion light having the high light intensity H2 is emitted. In the center concave portion 41A that has such a curvature as to also produce a predetermined light emission intensity in the normal direction, light B1a emitted in the normal direction is added to the direct emission light B1 from the LED chip 3, and thus it is possible to slightly increase a light intensity H1A.

As described above, in the LED light source 1A that has a light emission peak at a high diffusion angle and further includes the center concave portion 41A and the ring-shaped convex portion 42A solidified to have such a shape as to further produce a predetermined light emission intensity in the normal direction, it is possible to prevent a front surface intensity from becoming excessively low, to make uniform the brightness on the display screen and to enhance the display quality.

FIG. 3 shows an example where the light emission characteristics of the LED light source 1 shown in FIG. 1 and the LED light source 1A shown in FIG. 2 were actually measured; the horizontal axis represents a light diffusion angle, and the vertical axis represents a light intensity. As is obvious from this figure, the light emission characteristic HR1 produced by the LED light source 1 has the light emission peaks P1 and P2 in diffusion positions open at predetermined angles. The light emission characteristic HR2 produced by the LED light source 1A has not only light emission peaks NA and P2A in diffusion positions open at predetermined angles but also a third small light emission peak P3 in a direct emission direction in the center portion.

If the third light emission peak P3 is provided, low light amount portions D1 and D2 in which the light intensity is slightly lowered are generated. Hence, the curvatures of the center concave portion 41 and the ring-shaped convex portion 42 are changed, and thus it is possible to adjust the light intensity in the direct emission direction of the LED light source and in the vicinity thereof.

As described above, the center concave portion 41 is provided to reduce the light intensity in the LED light source direct emission direction, the ring-shaped convex portion 42 having the predetermined curvature is provided to increase the light intensity in the direction diffused at the predetermined angle, the curvatures of the center concave portion 41 and the ring-shaped convex portion 42 are changed to slightly increase the light intensity in the direct emission direction of the LED light source 1 and the shape of the solidified sealing resin 4 is adjusted, and thus it is possible to adjust the light emitted and distributed and increase the light intensity in an arbitrary direction, with the result that light having a desired light intensity can be emitted in a desired direction.

The fluorescent material used in the present embodiment is, for example, the red fluorescent material RF that receives the blue light emitted by the LED chip 3 to emit the red excitation light and the green fluorescent material GF that receives the blue light to emit the green excitation light. As the green fluorescent material GF, a plurality of green fluorescent materials (for example, two types, namely, the first green fluorescent material GF1 and the second green fluorescent material GF 2) that emit green light of different wavelengths are contained. In this configuration, a light emission characteristic over the wide range of a green light emission wavelength region is produced, and thus it is possible to reduce, even if the LED light emission characteristic depends on the color, variations in color over the entire backlight and stabilize the color reproduction range of the light emission colors.

For example, as shown in FIG. 4, a fluorescent material (for example, the first green fluorescent material GF1) that has a light emission peak around about 540 nm to produce a light emission characteristic GK1 and a fluorescent material (for example, the second green fluorescent material GF2) that has a light emission peak around about 530 nm to produce a light emission characteristic GK2 are mixed and used.

Then, the green fluorescent material GF obtained by mixing the first green fluorescent material GF1 and the second green fluorescent material GF2 produces a light emission characteristic GK (GK1+GK2), and thereby produces the light emission characteristic over the wide range of the green light emission wavelength region. As described above, two types of green fluorescent materials having different light emission peaks are mixed, and thus the light emission characteristic over the wide range of the green light emission wavelength region is produced, with the result that it is possible to reduce variations in color over the entire backlight and stabilize the color reproduction range of the light emission colors.

The green fluorescent material GF described above is preferably a fluorescent material that receives blue light to emit light in the green wavelength region; the green fluorescent material GF may be a silicate fluorescent material, a sulfide fluorescent material or a nitride fluorescent material. The components of the green fluorescent material GF are not limited.

The number of the types of mixed fluorescent materials within the same light emission wavelength region is not limited to two described above; it may be two or more; for example, three types of fluorescent materials may be mixed. As described above, a plurality of types of green fluorescent materials are mixed, and thus it is possible to further reduce variations in color over the entire backlight and stabilize the color reproduction range of the light emission colors.

When the fluorescent material is the red fluorescent material RF that receives the blue light to emit the red excitation light and the green fluorescent material GF that receives the blue light to emit the green excitation light, the red fluorescent material RF may have a plurality of red fluorescent materials that emit red light of different light emission peak wavelengths.

For example, a first red fluorescent material having a light emission peak around about 620 nm and a second red fluorescent material having a light emission peak around about 640 nm are mixed and used. In this configuration, a plurality of light emission peaks are produced in a red light emission wavelength region, and a light emission characteristic over the wide range of the red light emission wavelength region is produced. Thus, it is possible to reduce, even if the LED light emission characteristic depends on the color, variations in color over the entire backlight and stabilize the color reproduction range of the light emission colors.

Even in this case, the red fluorescent material RF may be obtained by mixing a plurality of types of red fluorescent materials having two or more different excitation wavelengths. The red fluorescent material RF described above is preferably a fluorescent material that receives blue light to emit light of the red wavelength region; as with the green fluorescent material GF, the red fluorescent material RF may be a silicate fluorescent material, a sulfide fluorescent material or a nitride fluorescent material. The components of the red fluorescent material RF are not limited.

When the fluorescent material is the red fluorescent material that receives the blue light to emit the red excitation light and the green fluorescent material that receives the blue light to emit the green excitation light, the red fluorescent material may have a plurality of red fluorescent materials that emit red light of different wavelengths, and furthermore the green fluorescent material may have a plurality of green fluorescent materials that emit green light of different wavelengths. In this configuration, a plurality of light emission peaks are produced in each of the red and green light emission wavelength regions, and a light emission characteristic over the wide range of a plurality of light emission wavelength regions is produced. Thus, it is possible to reduce, even if the LED light emission characteristic depends on the color, variations in color over the entire backlight and stabilize the color reproduction range of the light emission colors.

The fluorescent material may be a yellow fluorescent material that receives blue light to emit yellow excitation light; the blue light emitted by the blue LED chip 3 and the yellow light emitted by the fluorescent material may be combined to form white light. In this case, the yellow fluorescent material preferably has a plurality of yellow fluorescent materials that emit yellow light of different wavelengths. In this configuration, a plurality of light emission peaks are produced in a yellow light emission wavelength region, and a light emission characteristic over a wide range is produced. Thus, it is possible to reduce, even if the LED light emission characteristic depends on the color, variations in color over the entire backlight and stabilize the color reproduction range of the light emission colors.

The yellow fluorescent material described above is preferably a fluorescent material that receives blue light to emit light in the yellow wavelength region; the yellow fluorescent material may be a YAG fluorescent material, another oxide fluorescent material, a sulfide fluorescent material or a nitride fluorescent material. The components of the yellow fluorescent material are not limited.

The LED light sources 1 and 1A of the present embodiment have an emission surface formed in the shape of a diffusion lens that adjusts light emitted and distributed and a high diffusion-type light emission characteristic, and are configured such that a plurality of fluorescent materials having different light emission peaks within the light emission wavelength region of the same color are mixed, and thus it is possible to increase the flexibility of the color reproducibility. Hence, the LED backlight using the LED light source described above is an LED backlight which reduces variations in the light emission characteristic of each LED light source and in which no color variations in the chromaticity of the light emitted from the light emitting surface are produced.

The LED light source of a high diffusion type and the LED backlight of the present embodiment will now be described with reference to FIG. 5.

Symbols 1a, 1b and 1c in the figure represent LED light sources that are not a high diffusion type but are a standard type. A region A1 enclosed by broken lines is an illumination region of the LED light source 1a; a region A2 is an illumination region of the LED light source 1b; a region A3 is an illumination region of the LED light source 1c.

Symbols 1A, 1B and 1C each represent the LED light source of a high diffusion type; symbol B1 is an illumination region of the LED light source 1A; symbol B2 is an illumination region of the LED light source 1B; symbol B3 is an illumination region of the LED light source 1C. For example, as with the illumination region B2 of the LED light source 1B enclosed by thick broken lines in the figure, it is a high diffusion type that diffuses up to parts of the LED light sources 1A and 1C on both sides. In this state, light emitted from the LED light source 1B is mixed with light emitted from the LED light source 1A and light emitted from the LED light source 1C.

Hence, the LED light sources 1A, 1B and 1C of a high diffusion type are configured as an LED backlight BL1 where a plurality of LED light sources are provided such that the application regions of the adjacent LED light sources overlap each other, and thus it is possible to mix and average the light from the adjacent LED light sources, with the result that it is possible to obtain an LED backlight in which the brightness on the display screen is unlikely to become uniform and furthermore, color variations in the chromaticity of the emitted light are more unlikely to be produced.

As described above, in each LED light source, a plurality of fluorescent materials having different light emission peaks within the light emission wavelength region of the same color are mixed, and thus it is possible to individually reduce variations in color; in addition, the light of the adjacent light sources is mixed, and thus it is possible to facilitate the further reduction of the color variations and make uniform the backlight emission colors.

Hence, in the present embodiment, since variations in the brightness of an area are produced by overlapping of the light emission of a plurality of LED light sources, even if the light emission characteristic of the LED light source depends on the color, it is possible to effectively reduce variations in color over the entire LED backlight.

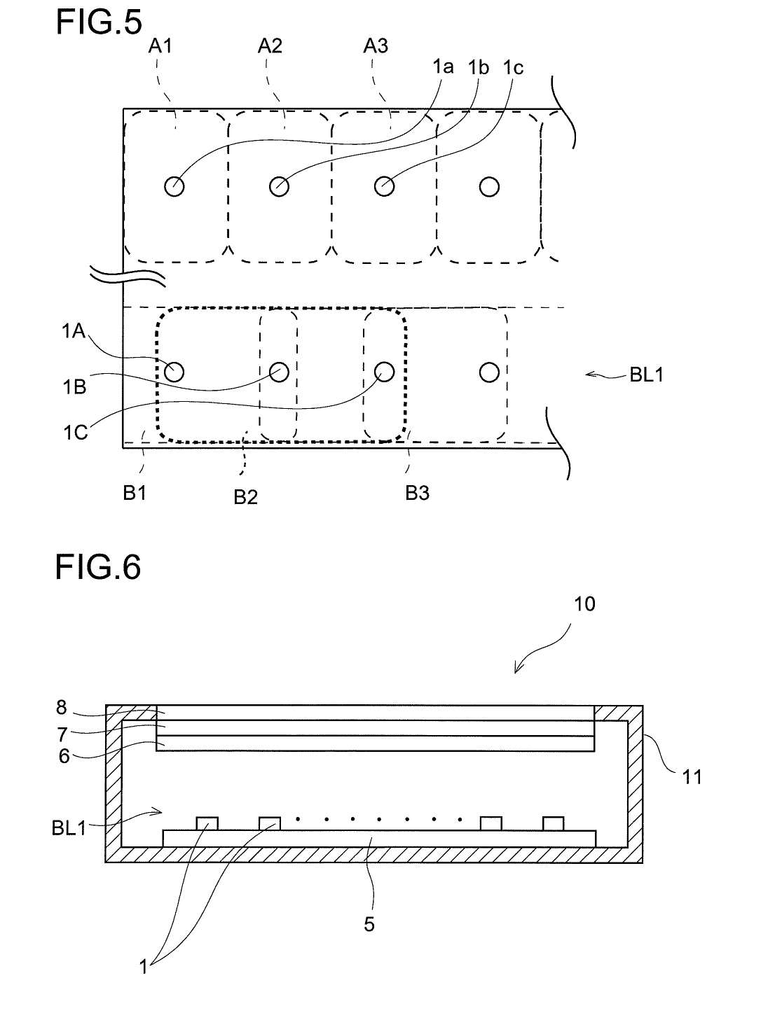

The LED backlight BL1 incorporating the LED light sources of the present embodiment and a liquid crystal display device 10 incorporating the LED backlight BL1 will now be described with reference to FIG. 6. As shown in the figure, in the liquid crystal display device 10, a plurality of LED light sources 1 are mounted on a substrate 5 with a predetermined pitch, and the LED backlight BL1, a diffusion plate 6, a lens sheet 7, a liquid crystal panel 8 and a frame member 11 are integrally combined.

The diffusion plate 6 and the lens sheet 7 are thin plate-shaped or film-shaped optical members for uniformly diffusing incoming light and enhancing the brightness; they have the function of diffusing the light emitted by the LED light source 1 and spreading the light over the entire region of the liquid crystal panel 8.

In the liquid crystal panel 8, liquid crystal materials are sealed in and sandwiched between two transparent glass substrates, a color filter and a polarization filter are stacked, a large number of pixels are formed in a lattice through switching elements formed in a lattice, a voltage fed into each of the switching elements is changed to vary the orientation of the liquid crystal, the amount of light that passes through each pixel is controlled and a predetermined image is displayed on the upper surface of the liquid crystal panel 8.

Since the liquid crystal panel 8 is an unluminous display panel, the liquid crystal panel 8 receives light (backlight) from the backlight to achieve the display function. Hence, when the light from the LED backlight BL1 can be uniformly applied to the entire surface of the liquid crystal panel 8 without variations in color, the display quality of the liquid crystal display device 10 is enhanced.

Although the light from the LED light sources, each being a point light source, is diffused and made uniform to increase the brightness and is applied to the liquid crystal panel 8 through the diffusion plate 6 and the lens sheet 7, if, in a direct-type LED backlight, the application region of each LED light source does not overlap the application region of the adjacent LED light source, and thus the light is not mixed, variations in color caused by the hue of each LED light source may be produced.

However, as in the present embodiment, each LED light source is a high diffusion type, and fluorescent materials emitting individual hues are simply configured by mixing a plurality of types of fluorescent materials that emit excitation light of a plurality of different wavelengths within the excitation light wavelength range of a predetermined color, and thus it is possible to reduce variations in the light emission characteristic of each LED light source. The application regions of the adjacent LED light sources overlap each other, and thus the light is easily mixed and averaged, with the result that it is possible to obtain an LED backlight capable of reducing the occurrence of variations in color over the entire display screen. Hence, in the present embodiment, variations in color are unlikely to be produced, the brightness on the display screen is unlikely to become uniform and thus it is possible to obtain a liquid crystal display device which reduces variations in color over the entire display screen and enhances the display quality.

Hence, when a TV reception device incorporates the liquid crystal display device described above, variations in the light emission characteristic of each LED light source are reduced, color variations in the chromaticity of the light emitted from the light emitting surface are not produced, an LED backlight that makes uniform the brightness on the display screen is used and thus it is possible to obtain a TV reception device which reduces variations in color over the entire display screen and enhances the display quality.

As described above, the LED light source of the present invention is simply configured, and thus it is possible to reduce variations in the light emission characteristic of each LED light source. In a direct-type LED backlight incorporating the LED light sources described above, the light from the LED light sources can be mixed and averaged, the brightness on the display screen is unlikely to become uniform and color variations in the chromaticity of the emitted light are more unlikely to be produced.

Hence, the LED backlight of the present invention is simply configured, and thus it is possible to reduce variations in the light emission characteristic of each LED light source and prevent color variations in the chromaticity of the light emitted from the light emitting surface.

In the liquid crystal display device and the TV reception device according to the present invention, the LED backlight described above is used, variations in color over the entire display screen are reduced and the display quality is enhanced.

### INDUSTRIAL APPLICABILITY

Hence, the LED light source and the LED backlight according to the present invention can be suitably utilized in the LED backlight of a liquid crystal display device or a TV reception device that is required to reduce variations in color on a screen, stabilize light emission brightness and enhance the quality.

### LIST OF REFERENCE SYMBOLS

1 LED light source
2 mounting substrate
3 LED chip
4 sealing resin
41, 41A center concave portion
42, 42A ring-shaped convex portion
5 substrate
6 diffusion plate
8 liquid crystal panel
10 liquid crystal display device
BL1 LED backlight
GF green fluorescent material
GF1 first green fluorescent material
GF2 second green fluorescent material
RF red fluorescent material
P1, P2 light emission peak
P3 third light emission peak

1. An LED light source comprising:
an LED chip that emits first light of a predetermined color;
a mounting substrate on which the LED chip is mounted; and
a sealing resin that contains a fluorescent material which receives the light from the LED chip to emit second light in an excitation light wavelength range of a predetermined color, the LED light source emitting, from a light emitting surface, third light obtained by mixing the first light and the second light,
wherein the fluorescent material includes a plurality of types of fluorescent materials that emit excitation light of a plurality of different wavelengths within the excitation light wavelength range of the predetermined color, and
the light emitting surface is formed in a shape of a diffusion lens portion that adjusts light emitted and distributed.

2. The LED light source of claim 1,
wherein the sealing resin is solidified to have such a shape as to have a light emission peak at a high diffusion angle such that the sealing resin forms the diffusion lens portion.

3. The LED light source of claim 1,
wherein the first light is blue light, the LED chip is a blue LED chip that emits blue light, the second light is red light and green light, the fluorescent material is a red fluorescent material that receives the blue light to emit red excitation light and a green fluorescent material that receives the blue light to emit green excitation light and the green fluorescent material includes a plurality of green fluorescent materials that emit green light of different wavelengths.

4. The LED light source of claim 3,
wherein the green fluorescent material is formed with a first green fluorescent material and a second green fluorescent material having different excitation wavelengths.

5. The LED light source of claim 1,
wherein the first light is blue light, the LED chip is a blue LED chip that emits blue light, the second light is red light and green light, the fluorescent material is a red fluorescent material that receives the blue light to emit red excitation light and a green fluorescent material that receives the blue light to emit green excitation light and the red fluorescent material includes a plurality of red fluorescent materials that emit red light of different wavelengths.

6. The LED light source of claim 5,
wherein the red fluorescent material is formed with a first red fluorescent material and a second red fluorescent material having different excitation wavelengths.

7. The LED light source of claim 1,
wherein the first light is blue light, the LED chip is a blue LED chip that emits blue light, the second light is red light and green light, the fluorescent material is a red fluorescent material that receives the blue light to emit red excitation light and a green fluorescent material that receives the blue light to emit green excitation light, the red fluorescent material includes a plurality of red fluorescent materials that emit red light of different wavelengths and the green fluorescent material includes a plurality of green fluorescent materials that emit green light of different wavelengths.

8. The LED light source of claim 2,
wherein the solidified sealing resin is shaped to include a center concave portion where an upper portion of the LED chip is depressed in a concave form and a ring-shaped convex portion where a circumference thereof protrudes in a ring-shaped convex form and is formed in a shape of a curved surface having a predetermined curvature that increases a light intensity in a predetermined diffusion direction.

9. The LED light source of claim 8,
wherein the curvatures of the center concave portion and the ring-shaped convex portion have a light emission peak at a high diffusion angle, and furthermore, the center concave portion and the ring-shaped convex portion are solidified to have such a shape as to also produce a predetermined light emission intensity in a normal direction.

10. A direct-type LED backlight in which a plurality of LED light sources arranged on a back surface of a liquid crystal panel applies light to the liquid crystal panel, the LED backlight comprising, as the LED light source, the LED light source of claim 1.

11. The LED backlight of claim 10,
wherein the plurality of LED light sources are provided such that application regions of adjacent LED light sources overlap each other.

12. A liquid crystal display device comprising:
a liquid crystal panel; and
the LED backlight of claim 10.

13. A TV reception device comprising:
the liquid crystal display device of claim 12.
